(19) United States
(12) Patent Application Publication
(10) Pub. No.: US 2026/0011552 A1
(43) Pub. Date: Jan. 8, 2026

(54) METHOD FOR PRODUCING VERTICAL NITRIDE SEMICONDUCTOR DEVICE AND VERTICAL NITRIDE SEMICONDUCTOR DEVICE

(71) Applicant: TOYODA GOSEI CO., LTD., Kiyosu-shi (JP)

(72) Inventor: Takaki NIWA, Aichi (JP)

(21) Appl. No.: 19/256,832

(22) Filed: Jul. 1, 2025

(30) Foreign Application Priority Data
Jul. 3, 2024 (JP) 2024-107095

(51) Int. Cl. H01L 21/02; H10D 62/85

(52) U.S. Cl. CPC H01L 21/0254; H01L 21/02389; H10D 62/8503

(57) ABSTRACT

A method for producing a vertical nitride semiconductor device includes: preparing a semiconductor substrate containing a Group III nitride semiconductor and having a donor element concentration of 1×10¹⁹ cm⁻³ or more; and forming a support layer containing a metal and having a thickness of 10 μm or more on a first main surface of the semiconductor substrate.

### CROSS-REFERENCE TO RELATED APPLICATION

This application is based on and claims priority under 35 USC 119 from Japanese Patent Application No. 2024-107095 filed on Jul. 3, 2024.

### TECHNICAL FIELD

The present invention relates to a method for producing a vertical nitride semiconductor device and a vertical nitride semiconductor device.

### BACKGROUND ART

In order to improve a performance of a semiconductor device, it is desired to reduce a resistance by increasing a dopant concentration in a semiconductor substrate constituting the semiconductor device. For example, in a vertical nitride semiconductor device disclosed in Patent Literature 1, a GaN substrate having a dopant concentration of 1×10¹⁹ cm⁻³ or more is used to reduce a substrate resistance and to achieve a low resistance.
Patent Literature 1: JP2021-12900A

### SUMMARY OF INVENTION

However, the inventors have found that, in the configuration disclosed in Patent Literature 1, since the dopant concentration in the GaN substrate is 1×10¹⁹ cm⁻³ or more, there is a problem that a thermal resistance increases due to a decrease in thermal conduction caused by phonon scattering and a heat dissipation property decreases. Therefore, in the vertical nitride semiconductor device, there is room for improvement in achieving both a low resistance and an improvement in heat dissipation property.

The present invention has been made in view of the above problems, and an object thereof to provide a vertical nitride semiconductor device achieving both a low resistance and a high heat dissipation property.

An aspect of the present invention provides a method for producing a vertical nitride semiconductor device including: a semiconductor substrate preparation step of preparing a semiconductor substrate made of a Group III nitride semiconductor and having a donor element concentration of 1×10¹⁹ cm⁻³ or more; and a support layer formation step of forming a support layer containing a metal and having a thickness of 10 μm or more on a first main surface of the semiconductor substrate.

Another aspect of the present invention provides a vertical nitride semiconductor device including: a semiconductor substrate made of a Group III nitride semiconductor and having a donor element concentration of 1×10¹⁹ cm⁻³ or more; and a support layer containing a metal and having a thickness of 10 μm or more, which is formed on a first main surface of the semiconductor substrate.

In the method for producing a vertical nitride semiconductor device according to the above aspect, since the semiconductor substrate has a high donor element concentration of 1×10¹⁹ cm⁻³ or more, a substrate resistance can be reduced. Further, since the semiconductor substrate has a low resistance, a width of a depletion layer in a Schottky barrier layer formed at a junction portion between the semiconductor substrate and the support layer containing a metal can be reduced, and a current easily flows due to a tunnel effect. Therefore, a contact resistance between the semiconductor substrate and the support layer can be reduced. Accordingly, a vertical nitride semiconductor device having a low resistance can be produced. Further, since the support layer containing a metal is formed on the semiconductor substrate, heat dissipation through the support layer is promoted, and a heat dissipation property is improved. In addition, since the support layer contains a metal and has a thickness of 10 μm or more and thus has relatively high rigidity, it is possible to prevent breakage of the semiconductor substrate and it is possible to improve handleability.

In the vertical nitride semiconductor device according to the another aspect, since the donor element concentration in the semiconductor substrate is 1×10¹⁹ cm⁻³ or more, a substrate resistance can be reduced, a contact resistance between the semiconductor substrate and the support layer can be reduced, and a resistance of the vertical nitride semiconductor device can be reduced. Further, since the support layer containing a metal is formed on the semiconductor substrate, heat dissipation through the support layer is promoted, and a heat dissipation property is improved. In addition, since the support layer contains a metal and has a thickness of 10 μm or more and thus has relatively high rigidity, it is possible to prevent breakage of the semiconductor substrate and it is possible to improve handleability.

As described above, according to the above aspects, a vertical nitride semiconductor device achieving both a low resistance and a high heat dissipation property is provided.

### BRIEF DESCRIPTION OF DRAWINGS

FIG. 1 is a conceptual diagram showing a configuration of a vertical nitride semiconductor device according to a first embodiment.

FIG. 2 is a flowchart showing a method for producing a vertical nitride semiconductor device according to the first embodiment.

FIG. 3 is a conceptual diagram illustrating the method for producing a vertical nitride semiconductor device according to the first embodiment.

FIG. 4 is a conceptual diagram illustrating a method for producing a vertical nitride semiconductor device according to a first modification.

### DESCRIPTION OF EMBODIMENTS

The method for producing a vertical nitride semiconductor device preferably further includes a thinning step of thinning the semiconductor substrate after the semiconductor substrate preparation step, in which the support layer formation step is performed after the thinning step. In this case, the heat dissipation property can be further improved by forming a thinned semiconductor substrate.

The method for producing a vertical nitride semiconductor device preferably further includes a semiconductor layer formation step of forming a semiconductor layer on a second main surface of the semiconductor substrate after the semiconductor substrate preparation step, in which the support layer formation step is performed after the semiconductor layer formation step. In this case, the semiconductor layer is formed before the support layer is formed, and the semiconductor layer can be stably formed.

In the method for producing a vertical nitride semiconductor device, the support layer formation step is preferably performed at an atmosphere temperature of 150° C. or lower. Since the semiconductor substrate has a high donor element concentration of 1×10¹⁹ cm⁻³ or more, the contact resistance between the semiconductor substrate and the support layer is reduced. Therefore, in the support layer formation step, it is possible to junction the semiconductor substrate and the support layer without reducing the contact resistance by alloying a junction portion between the semiconductor substrate and the support layer at an atmosphere temperature of 150° C. or lower. As a result, in the support layer formation step, it is possible to prevent damage to the semiconductor layer due to a stress caused by a difference in thermal expansion coefficient between the semiconductor substrate and the support layer, and it is possible to maintain a performance of the vertical nitride semiconductor device.

In the method for producing a vertical nitride semiconductor device, a heat treatment is not performed in the support layer formation step. In this case, in the support layer formation step, it is possible to more reliably prevent the damage to the semiconductor layer due to heat, and it is possible to maintain the performance of the vertical nitride semiconductor device.

In the method for producing a vertical nitride semiconductor device, the semiconductor substrate preferably has a thickness within a range of 20 μm to 200 μm. In this case, the heat dissipation property can be improved while maintaining a function of the semiconductor substrate.

In the method for producing a vertical nitride semiconductor device, the support layer preferably has a thickness of 100 μm or more. In this case, an effect of improving the heat dissipation property by the support layer is sufficiently obtained, and since the support layer has sufficient rigidity, the handleability of the vertical nitride semiconductor device can be improved.

In the vertical nitride semiconductor device, the semiconductor substrate preferably has a thickness within a range of 20 μm to 200 μm. In this case, the heat dissipation property can be improved while maintaining a function of the semiconductor substrate.

In the vertical nitride semiconductor device, the support layer preferably has a thickness of 100 μm or more. In this case, an effect of improving the heat dissipation property by the support layer is sufficiently obtained, and since the support layer has sufficient rigidity, the handleability of the vertical nitride semiconductor device can be improved.

In the vertical nitride semiconductor device, a junction portion between the semiconductor substrate and the support layer is preferably not alloyed. In this case, since heating for alloying is unnecessary when forming the support layer, it is possible to prevent damage to the semiconductor layer due to a stress generated during heating and cooling based on a difference in thermal expansion coefficient between the support layer and the semiconductor substrate, and it is possible to maintain the performance of the vertical nitride semiconductor device.

### First Embodiment

### 1. Outline of Configuration of Vertical Nitride Semiconductor Device 1

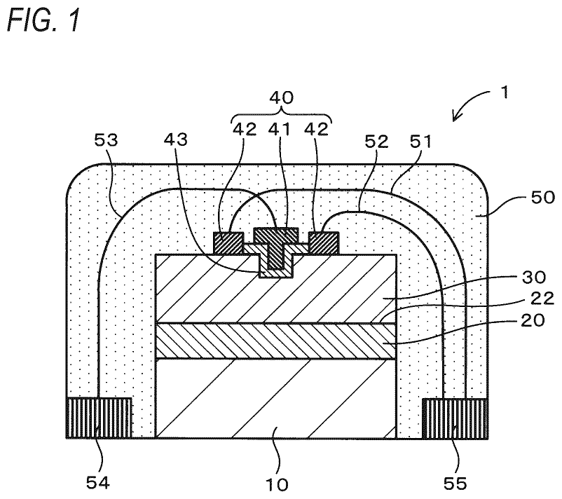

A configuration of a vertical nitride semiconductor device 1 according to a first embodiment will be described below. As shown in FIG. 1, the vertical nitride semiconductor device 1 according to the first embodiment has a structure in which a support layer 10, a semiconductor substrate 20, a semiconductor layer 30, and a front surface element 40 are stacked in this order and sealed with a sealing resin 50. Hereinafter, each configuration and forming method will be described in detail.

### 1-1. Semiconductor Substrate 20

The semiconductor substrate 20 is a substrate made of a Group III nitride semiconductor. In the present embodiment, a gallium nitride (GaN) substrate is used as the semiconductor substrate 20 and contains a donor element which is an impurity. The donor element can be, for example, any of oxygen (O), silicon (Si), and germanium (Ge). The semiconductor substrate 20 has a donor element concentration of 1×10¹⁹ cm⁻³ or more. In the present embodiment, the semiconductor substrate 20 contains O as a donor element.

In the semiconductor substrate 20, in the case where the donor element concentration is more than 1×10²² cm⁻³, crystallinity of the semiconductor substrate 20 may decrease, and thus the donor element concentration is preferably 1×10²² cm⁻³ or less. Accordingly, the crystallinity of the semiconductor substrate 20 can be prevented from decreasing, and the performance of the vertical nitride semiconductor device 1 can be improved.

A thickness of the semiconductor substrate 20 is not limited, and may be within a range of 20 μm to 200 μm. The thickness of the semiconductor substrate is generally 300 μm to 400 μm, and the thickness of the semiconductor substrate 20 in the present embodiment is sufficiently thin. By sufficiently reducing the thickness of the semiconductor substrate 20, even in the case where a Schottky barrier is formed between the semiconductor substrate 20 and the support layer 10, a barrier thickness can be sufficiently reduced, and the contact resistance between the semiconductor substrate 20 and the support layer 10 can be reduced.

As described above, a method of forming the semiconductor substrate 20 is sufficiently a method capable of incorporating the donor element at a high concentration into the semiconductor substrate 20, and for example, an ammonothermal method or an oxide vapor phase epitaxy (OVPE) method can be used. In the present embodiment, the semiconductor substrate 20 doped with an oxygen concentration of 1×10¹⁹ cm⁻³ or more, preferably 5×10¹⁹ cm⁻³ or more by the ammonothermal method is prepared. The semiconductor substrate 20 is formed as a low-resistance GaN substrate by autodoping oxygen during growth using the ammonothermal method.

In the present embodiment, it has been found that a thermal resistance of the semiconductor substrate 20 having a donor element concentration of 5×10¹⁹ cm⁻³ is nearly twice a thermal resistance of a semiconductor substrate having a dopant element concentration of 1×10¹⁸ cm⁻³ produced by a conventional HVPE method, as determined by transient thermal resistance analysis using a transient duel interface (TDI) method according to JEDEC-JESD51-14.

### 1-2. Support Layer 10

The support layer 10 is made of a material containing a metal. As the material of the support layer 10, a metal simple substance such as Cu, Al, Ti, Ni, Mg, Mo, V, Au, or Ag, an alloy such as CuW, TiN, or AlCu, a combination of two or more of these, or the like can be used. Instead of these, a composite material obtained by combining a metal such as a direct copper bonding (DCB) substrate and another support material can be used. In addition, the support layer 10 may be formed of a single layer or may be formed by stacking two or more layers, and may have a configuration in which, for example, a layer made of Cu is sandwiched between layers made of a DCB substrate.

A thickness of the support layer 10 is 10 μm or more, and preferably 50 μm to 100 μm. In the case where the thickness of the support layer 10 is less than 10 μm, sufficient rigidity cannot be obtained, and the effect of improving heat dissipation property cannot be sufficiently obtained. On the other hand, an upper limit of the thickness of the support layer 10 is not set, but excessively increasing the thickness of the support layer 10 is not preferred since the effect of improving heat dissipation property reaches a plateau and a cost increases.

The support layer 10 can be formed by pressure-bonding a metal plate or a composite material containing a metal constituting the support layer 10 prepared in advance to a back surface of the semiconductor substrate 20 in a normal temperature environment of 1×10⁻⁶ Pa or less set by a vacuum apparatus. At this time, an oxide film on the back surface of the semiconductor substrate 20 may be removed in advance, or the oxide film may be actively formed by an oxygen radical treatment. Note that, when the support layer 10 is to be formed, a heat treatment for alloying is not required. The support layer 10 can be formed at an environmental temperature of lower than 450° C., and preferably 150° C. or lower. Accordingly, it is possible to prevent performance deterioration of the semiconductor layer 30 to be described later.

The support layer 10 is attached to the back surface of the semiconductor substrate 20, and thus has a function as a drain electrode in addition to a function of supporting the semiconductor substrate 20. Note that, a drain electrode (not shown) may be formed on the back surface of the semiconductor substrate 20 separately from the support layer 10, and then the support layer 10 may be provided on the back surface of the semiconductor substrate 20.

Since the semiconductor substrate 20 and the support layer 10 have the above configuration, the contact resistance between the support layer 10 and the semiconductor substrate 20 can be 1×10⁻⁵ Ωcm² or less, and more preferably 5×10⁻⁶ Ωcm² or less. Accordingly, the junction between the support layer 10 and the semiconductor substrate 20 can be non-alloy-ohmic junction without alloying, and sufficient ohmic contact can be realized by room temperature junction.

### 1-3. Semiconductor Layer 30 and Front Surface Element 40

The semiconductor layer 30 is formed on an upper surface 22 of the semiconductor substrate 20. A configuration of the semiconductor layer 30 is not limited and may be a desired semiconductor layer. In the present embodiment, a Group III nitride semiconductor layer is formed as the semiconductor layer 30. A method for forming the semiconductor layer 30 is not limited, and a known method can be used. In the present embodiment, the semiconductor layer 30 is formed by an epitaxial growth method. The semiconductor layer 30 is formed after the semiconductor substrate 20 is formed and before the support layer 10 is formed.

The front surface element 40 is formed on the semiconductor layer 30. A configuration of the front surface element 40 is not limited, and includes electrodes 41 and 42. A method of forming the front surface element 40 is not limited, and the front surface element 40 can be formed by a desired method. The front surface element 40 is formed after the semiconductor layer 30 is formed and before the support layer 10 is formed. After the semiconductor layer 30 and the front surface element 40 are formed, the back surface of the semiconductor substrate 20 can be cleaned. The electrodes 41 and 42 are connected to leads 54 and 55 by bonding wires 51, 52, and 53, respectively.

### 1-4. Sealing Resin 50

The sealing resin 50 seals a stacked body including the support layer 10, the semiconductor substrate 20, the semiconductor layer 30, and the front surface element 40 together with the bonding wires 51, 52, and 53 and the leads 54 and 55. A material of the sealing resin 50 is not limited, and a known material can be used.

### 2. Method for Producing Vertical Nitride Semiconductor Device 1

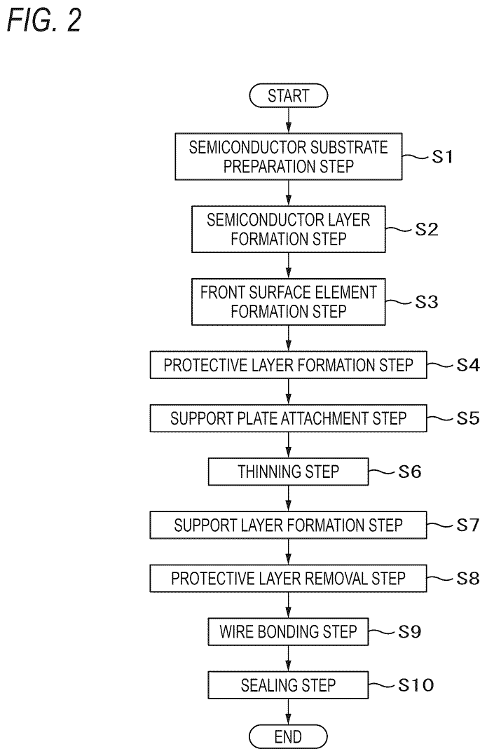

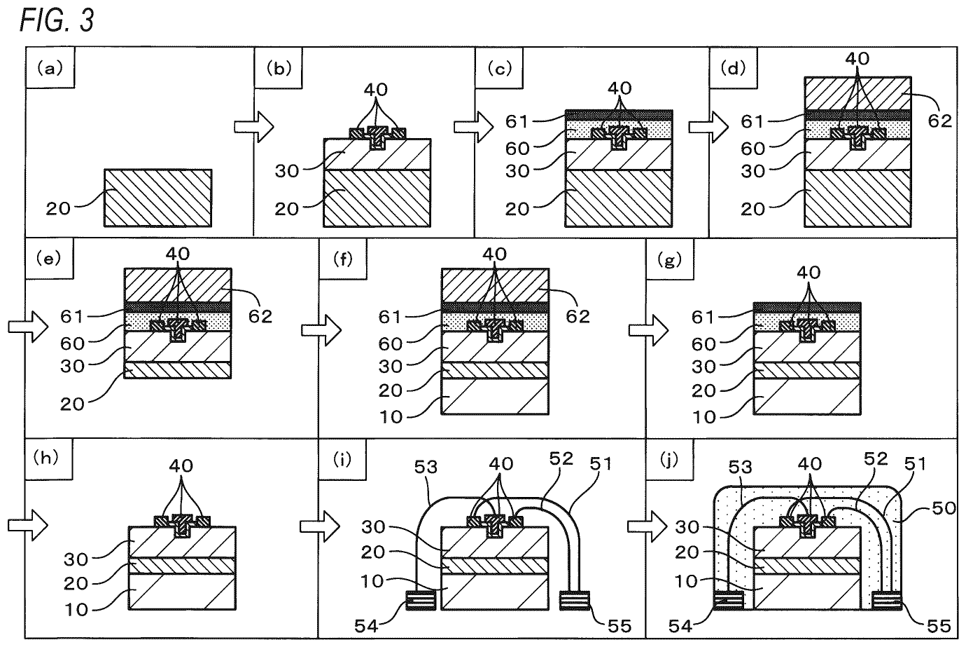

Next, a method for producing the vertical nitride semiconductor device 1 according to the present embodiment will be described with reference to a flowchart shown in FIG. 2 and a conceptual diagram shown in FIG. 3. The method for producing the vertical nitride semiconductor device 1 according to the present embodiment includes a semiconductor substrate preparation step S1, a semiconductor layer formation step S2, a front surface element formation step S3, a protective layer formation step S4, a support plate attachment step S5, a thinning step S6, a support layer formation step S7, a protective layer removal step S8, a wire bonding step S9, and a sealing step S10.

First, in the semiconductor substrate preparation step S1, as shown in (a) of FIG. 3, the above semiconductor substrate 20 is prepared. In the present embodiment, the semiconductor substrate 20 is formed by the ammonothermal method as described above. Accordingly, the semiconductor substrate 20 is formed to contain O as a donor element at a high concentration.

Next, in the semiconductor layer formation step S2, as shown in (b) of FIG. 3, the semiconductor layer 30 as an epitaxial thin film is formed on the upper surface 22 of the semiconductor substrate 20 by a MOCVD method or the like, and thereafter, in the front surface element formation step S3, the front surface element 40 is formed on the semiconductor layer 30. In the present embodiment, the front surface element 40 is a trench MOSFET or the like.

In the protective layer formation step S4, as shown in (c) of FIG. 3, a protective resist 60 covering the semiconductor layer 30 and the front surface element 40 is formed, and a double-sided adhesive UV film 61 is formed on an upper surface of the protective resist 60.

Next, in the support plate attachment step S5, as shown in (d) of FIG. 3, a support plate 62 is attached to the double-sided adhesive UV film 61. Then, in the thinning step S6, as shown in (e) of FIG. 3, the back surface (first main surface) of the semiconductor substrate 20 is ground to reduce the thickness of the semiconductor substrate 20 to 20 μm to 200 μm, thereby thinning the semiconductor substrate 20.

Thereafter, in the support layer formation step S7, as shown in (f) of FIG. 3, the support layer 10 is formed on the back surface of the semiconductor substrate 20. In the present embodiment, the oxide film is removed from the back surface of the semiconductor substrate 20 with HCl, then the support layer 10 is pressure-bonded to the back surface of the semiconductor substrate 20 in a normal temperature environment of 1×10⁻⁶ Pa or less set by a vacuum apparatus.

Thereafter, in the protective layer removal step S8, as shown in (g) of FIG. 3, the support plate 62 is removed by UV irradiation, and further, as shown in (h) of FIG. 3, the protective resist 60 and the double-sided adhesive UV film 61 are peeled off using a resist peeling liquid.

Then, in the wire bonding step S9, as shown in (i) of FIG. 3, the front surface element 40 and the leads 54 and 55 are connected by the bonding wires 51 to 53. Thereafter, in the sealing step S10, as shown in (j) of FIG. 3, the whole is sealed with the sealing resin 50, and the flow is ended.

### 3. Operations and Effects

In the method for producing a vertical nitride semiconductor device according to the present embodiment, since the semiconductor substrate 20 has a high donor element concentration of 1×10¹⁹ cm⁻³ or more, the substrate resistance can be reduced. Further, since the semiconductor substrate 20 has a low resistance, a width of a depletion layer in a Schottky barrier layer formed at a junction portion between the semiconductor substrate 20 and the support layer 10 containing a metal can be reduced, and a current easily flows due to a tunnel effect. Therefore, a contact resistance between the semiconductor substrate 20 and the support layer 10 can be reduced. Accordingly, the vertical nitride semiconductor device 1 having a low resistance can be produced. Further, since the support layer 10 containing a metal is attached to the semiconductor substrate 20, heat dissipation through the support layer 10 is promoted, and the heat dissipation property is improved. In addition, since the support layer 10 contains a metal and has a thickness of 10 μm or more and thus has relatively high rigidity, it is possible to prevent breakage of the semiconductor substrate 20 and it is possible to improve the handleability.

In addition, the method for producing a vertical nitride semiconductor device 1 according to the present embodiment includes the thinning step S6 of thinning the semiconductor substrate 20 after the semiconductor substrate preparation step S1, in which the support layer formation step S7 is performed after the thinning step S6. Accordingly, the heat dissipation property can be further improved by forming the thinned semiconductor substrate 20.

In addition, the method for producing a vertical nitride semiconductor device 1 according to the present embodiment includes the semiconductor layer formation step S2 of forming the semiconductor layer 30 on the upper surface (second main surface) of the semiconductor substrate 20 after the semiconductor substrate preparation step S1, in which the support layer formation step S7 is performed after the semiconductor layer formation step S2. Accordingly, the semiconductor layer 30 is formed before the support layer 10 is formed, and the semiconductor layer 30 can be stably formed.

In addition, in the method for producing the vertical nitride semiconductor device 1 according to the present embodiment, the support layer formation step S7 is performed at an atmosphere temperature of 150° C. or lower. Accordingly, in the support layer formation step S7, it is possible to prevent damage to the semiconductor layer 30 due to a stress caused by a difference in thermal expansion coefficient between the semiconductor substrate 20 and the support layer 10, and it is possible to maintain the performance of the vertical nitride semiconductor device 1.

In addition, in the method for producing the vertical nitride semiconductor device 1 according to the present embodiment, a heat treatment is not performed in the support layer formation step S7. Accordingly, in the support layer formation step S7, it is possible to more reliably prevent the damage to the semiconductor layer 30 due to heat, and it is possible to maintain the performance of the vertical nitride semiconductor device 1.

In addition, in the method for producing the vertical nitride semiconductor device 1 according to the present embodiment, the semiconductor substrate 20 has a thickness within a range of 20 μm to 200 μm. Accordingly, the heat dissipation property can be improved while maintaining the function of the semiconductor substrate 20.

In addition, in the method for producing the vertical nitride semiconductor device 1 according to the present embodiment, the support layer 10 has a thickness of 100 μm or more. Accordingly, the effect of improving the heat dissipation property by the support layer 10 is sufficiently obtained, and since the support layer 10 has sufficient rigidity, the handleability of the vertical nitride semiconductor device 1 can be improved.

In addition, in the method for producing the vertical nitride semiconductor device 1 according to the present embodiment, since the donor element concentration in the semiconductor substrate 20 is 1×10¹⁹ cm⁻³ or more, preferably 5×10¹⁹ cm⁻³ or more, the substrate resistance can be reduced, the contact resistance between the semiconductor substrate 20 and the support layer 10 can be reduced, and the resistance of the vertical nitride semiconductor device 1 can be reduced. Further, since the support layer 10 containing a metal is formed on the semiconductor substrate 20, heat the dissipation through the support layer 10 is promoted, and the heat dissipation property is improved. In addition, since the support layer 10 contains a metal and has a thickness of 10 μm or more and thus has relatively high rigidity, it is possible to prevent the breakage of the semiconductor substrate 20 and it is possible to improve the handleability.

In the method for producing the vertical nitride semiconductor device 1 according to the present embodiment, the semiconductor substrate 20 has a thickness within a range of 20 μm to 200 μm. Accordingly, the heat dissipation property can be improved while maintaining the function of the semiconductor substrate 20.

In addition, in the vertical nitride semiconductor device 1 according to the present embodiment, the support layer 10 has a thickness of 100 μm or more. Accordingly, the effect of improving the heat dissipation property by the support layer 10 is sufficiently obtained, and since the support layer 10 has sufficient rigidity, the handleability of the vertical nitride semiconductor device 1 can be improved.

In addition, in the vertical nitride semiconductor device 1 according to the present embodiment, the junction portion between the semiconductor substrate 20 and the support layer 10 is not alloyed. Accordingly, since heating for alloying is unnecessary when forming the support layer 10, it is possible to prevent the damage to the semiconductor layer 30 due to a stress generated during heating and cooling based on a difference in thermal expansion coefficient between the support layer 10 and the semiconductor substrate 20, and it is possible to maintain the performance of the vertical nitride semiconductor device 1.

Note that, in the present embodiment, in the method for producing the vertical nitride semiconductor device 1 shown in FIG. 3, the double-sided adhesive UV film 61 is used in the protective layer formation step S4. Instead, an attaching wax may be used instead. In this case, in the protective layer removal step S8, the support plate 62 can be peeled off from the protective resist 60 by removing the attaching wax by heating instead of UV irradiation. A heating temperature for removing the attaching wax may be 150° C. or lower.

In addition, in the present embodiment, in the method for producing the vertical nitride semiconductor device 1 shown in FIG. 3, the double-sided adhesive UV film 61 is formed in the protective layer formation step S4, but the double-sided adhesive UV film 61 may not be formed, and the support plate 62 may be directly attached to the protective resist 60 in the support plate attachment step S5. In this case, in the protective layer removal step S8, the support plate 62 is removed together with the protective resist 60 using the resist peeling liquid.

In addition, in the present embodiment, in the method for producing the vertical nitride semiconductor device 1 shown in FIG. 3, in the thinning step S6, as shown in (e) of FIG. 3, the semiconductor substrate 20 is thinned by grinding the back surface (first main surface) of the semiconductor substrate 20. Instead, the back surface side of the semiconductor substrate 20 may be cut using a laser such that the semiconductor substrate 20 has a predetermined thickness. In this case, a member cut from the semiconductor substrate 20 can be reused as the semiconductor substrate 20 of the vertical nitride semiconductor device 1 to be formed later.

In addition, in the present embodiment, in the method for producing the vertical nitride semiconductor device 1 shown in FIG. 3, in the support layer formation step S7, the support layer 10 is attached to the back surface of the semiconductor substrate 20 by pressure bonding in a vacuum state. Instead, Ni, Ti, Cu, or the like may be deposited on the back surface of the semiconductor substrate 20 to activate the back surface of the semiconductor substrate 20, and then the support layer 10 may be attached thereto by pressure bonding.

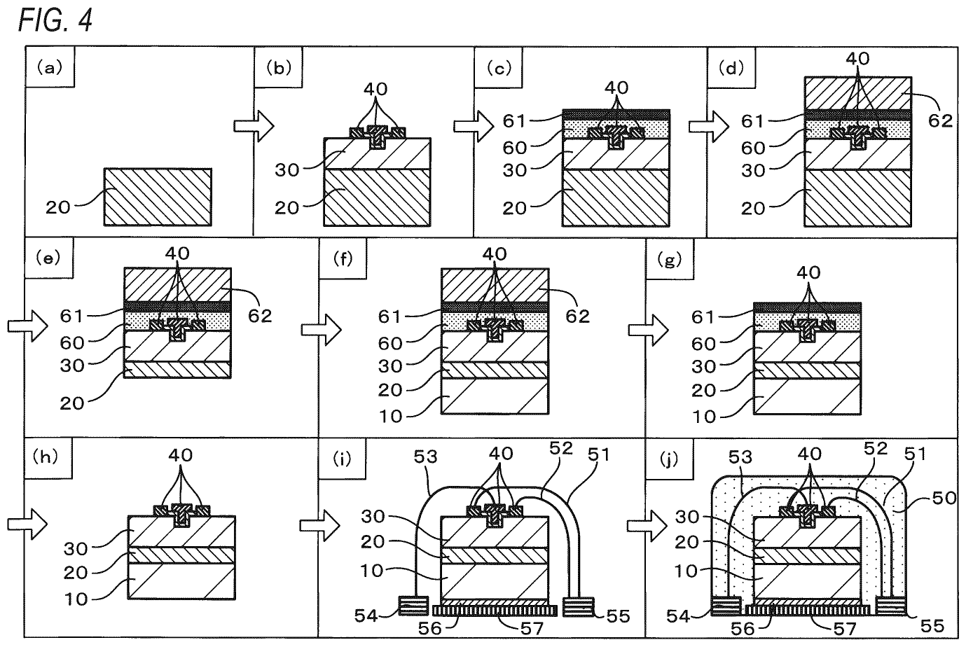

As in a first modification shown in FIG. 4, as shown in (i) of FIG. 4, the front surface element 40 and the leads 54 and 55 may be connected by the bonding wires 51 to 53, and the support layer 10 may be junctioned to a die pad via a die attach 56. The die attach 56 can be formed of, for example, solder. Note that, in the first modification shown in FIG. 4, the same components as those of the first embodiment shown in FIG. 3 are denoted by the same reference numerals, and the description thereof is omitted.

As described above, according to the present embodiment and the modification, the vertical nitride semiconductor device 1 achieving both a low resistance and a high heat dissipation property can be provided.

The present invention is not limited to the above embodiment and modification, and may be applied to various embodiments without departing from the gist of the present invention.

### REFERENCE SIGNS LIST

1 vertical nitride semiconductor device
10 support layer
20 semiconductor substrate
30 semiconductor layer
40 front surface element
41, 42 electrode
50 sealing resin
51, 52, 53 bonding wire
54, 55 lead
56 die attach
60 protective resist
61 double-sided adhesive UV film
62 support plate

What is claimed is:

1. A method for producing a vertical nitride semiconductor device, comprising:
preparing a semiconductor substrate containing a Group III nitride semiconductor and having a donor element concentration of 1×10¹⁹ cm⁻³ or more; and
forming a support layer containing a metal and having a thickness of 10 μm or more on a first main surface of the semiconductor substrate.

2. The method for producing a vertical nitride semiconductor device according to claim 1, further comprising:
thinning the semiconductor substrate after the preparing of the semiconductor substrate, wherein
the forming of the support layer is performed after the thinning.

3. The method for producing a vertical nitride semiconductor device according to claim 1, further comprising:
forming a semiconductor layer on a second main surface of the semiconductor substrate after the preparing of the semiconductor substrate, wherein
the forming of the support layer is performed after the forming of the semiconductor layer.

4. The method for producing a vertical nitride semiconductor device according to claim 2, further comprising:
forming a semiconductor layer on a second main surface of the semiconductor substrate after the preparing of the semiconductor substrate, wherein
the forming of the support layer is performed after the forming of the semiconductor layer.

5. The method for producing a vertical nitride semiconductor device according to claim 1, wherein the forming of the support layer is performed at an atmosphere temperature of 150° C. or lower.

6. The method for producing a vertical nitride semiconductor device according to claim 2, wherein the forming of the support layer is performed at an atmosphere temperature of 150° C. or lower.

7. The method for producing a vertical nitride semiconductor device according to claim 1, wherein a heat treatment is not performed in the forming of the support layer.

8. The method for producing a vertical nitride semiconductor device according to claim 2, wherein a heat treatment is not performed in the forming of the support layer.

9. The method for producing a vertical nitride semiconductor device according to claim 1, wherein the semiconductor substrate has a thickness within a range of 20 μm to 200 μm.

10. The method for producing a vertical nitride semiconductor device according to claim 2, wherein the semiconductor substrate has a thickness within a range of 20 μm to 200 μm.

11. The method for producing a vertical nitride semiconductor device according to claim 1, wherein the support layer has a thickness of 100 μm or more.

12. The method for producing a vertical nitride semiconductor device according to claim 2, wherein the support layer has a thickness of 100 μm or more.

13. A vertical nitride semiconductor device comprising:
a semiconductor substrate containing a Group III nitride semiconductor and having a donor element concentration of 1×10¹⁹ cm⁻³ or more; and
a support layer containing a metal and having a thickness of 10 μm or more, which is formed on a first main surface of the semiconductor substrate.

14. The vertical nitride semiconductor device according to claim 13, wherein the semiconductor substrate has a thickness within a range of 20 μm to 200 μm.

15. The vertical nitride semiconductor device according to claim 13, wherein the support layer has a thickness of 100 μm or more.

16. The vertical nitride semiconductor device according to claim 14, wherein the support layer has a thickness of 100 μm or more.

17. The vertical nitride semiconductor device according to claim 13, wherein a junction portion between the semiconductor substrate and the support layer is not alloyed.

18. The vertical nitride semiconductor device according to claim 14, wherein a junction portion between the semiconductor substrate and the support layer is not alloyed.
